(19) United States
(12) Patent Application Publication
(10) Pub. No.: US 2012/0106077 A1
(43) Pub. Date: May 3, 2012

(54) Extruding Material Through A Die To Produce A Computer Chassis

(76) Inventors: Mark S. Tracy, Tomball, TX (US); Earl W. Moore, Cypress, TX (US); Paul J. Doczy, Austin, TX (US)

(21) Appl. No.: 13/126,015

(22) PCT Filed: Oct. 31, 2008
(86) PCT No.: PCT/US2008/082018

§ 371 Date: Apr. 26, 2011

(51) Int. Cl. G06F 1/16; B23P 17/00; H05K 13/00; B21C 23/00

(52) U.S. Cl. 361/679.56; 361/679.02; 361/679.55; 361/679.6; 72/253.1; 29/592.1

(57) ABSTRACT

A method that comprises extruding material through a die to produce a notebook computer chassis having multiple sides that encapsulate a volume.

### BACKGROUND

Each notebook computer generally comprises a chassis that is built by piecing together several components during the manufacturing process. Chassis built in this manner tend to make access to the circuit components (e.g., for repair) difficult. Further, such chassis are often undesirably weak, leaving the chassis' contents prone to severe damage upon experiencing forceful impact (e.g., when dropped to the ground). Further still, such chassis are undesirably expensive to manufacture. Yet further still, chassis that comprise multiple components tend to be aesthetically unpleasant. A stronger, less expensive, more flexible and aesthetically pleasing notebook chassis that provides easy access to its contents is desirable.

### BRIEF DESCRIPTION OF THE DRAWINGS

For a detailed description of exemplary embodiments of the invention, reference will now be made to the accompanying drawings in which:

FIG. 1 shows an illustrative notebook computer fabricated in accordance with embodiments;

FIG. 2 shows an illustrative die usable in accordance with embodiments;

FIG. 3 shows an illustrative chassis built in accordance with embodiments; and

FIG. 4 shows a flow diagram of an illustrative method, in accordance with embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Disclosed herein are various embodiments of an extruded computer chassis that overcomes the problems described above. In at least some of these embodiments, a die is fabricated in accordance with a cross-section of the desired notebook chassis. A desired material with which the chassis will be fabricated (e.g., titanium, metal alloys, aerospace-grade aluminum such as AL 6062-T6, etc.) is heated into a molten state and is subsequently extruded through the die. The material passed through the die is cooled. The result of this process is a chassis whose cross-sectional shape and dimensions conform to those of the die. Once the chassis cools, it is cut (e.g., using a stamping machine or CNC cutting machine) to create orifices through which keyboards, touchpads, etc. may be mounted.

Once the chassis has been fabricated, circuit components are slid into the chassis for easy access. A display is mounted to the chassis and is electronically coupled to the circuit components within the chassis. End caps are mounted to the chassis. The chassis may be anodized to a particular color, if desired. The chassis is then complete. This manufacturing method is superior to other methods at least because it produces notebook chassis that are stronger, less expensive, more flexible and more aesthetically pleasing than those produced by such other methods. A detailed description of the manufacturing process follows.

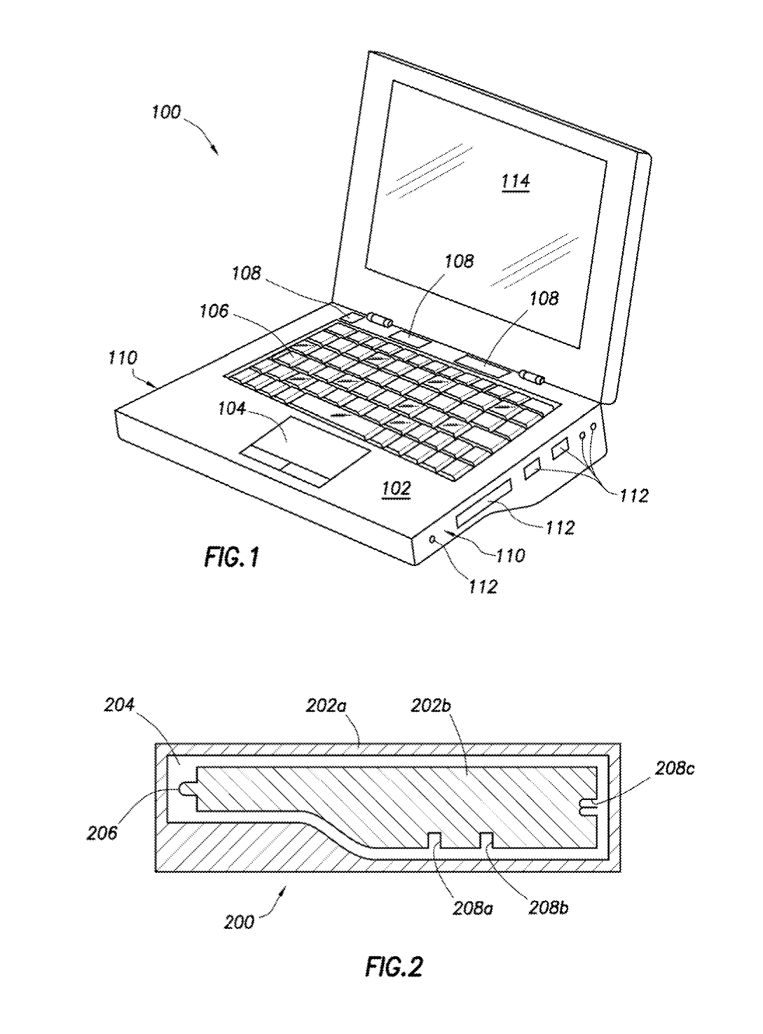

FIG. 1 shows a notebook computer (“notebook”) 100. The notebook 100 comprises a chassis 102, a touchpad 104, a keyboard 106, miscellaneous features 108 (e.g., power button, volume controls), endcaps 110, plug-in features 112 (e.g., universal serial bus (USB) ports, bays, jacks) and a display 114. The notebook 100 is merely illustrative of electronic devices to which the fabrication technique disclosed herein may apply. The technique disclosed herein may be adapted to various types of notebooks 100, as well as to different kinds of computers besides notebooks (e.g., personal digital assistants, mobile phones, desktop computers, etc.). The notebook 100 is fabricated using an extrusion process as described below.

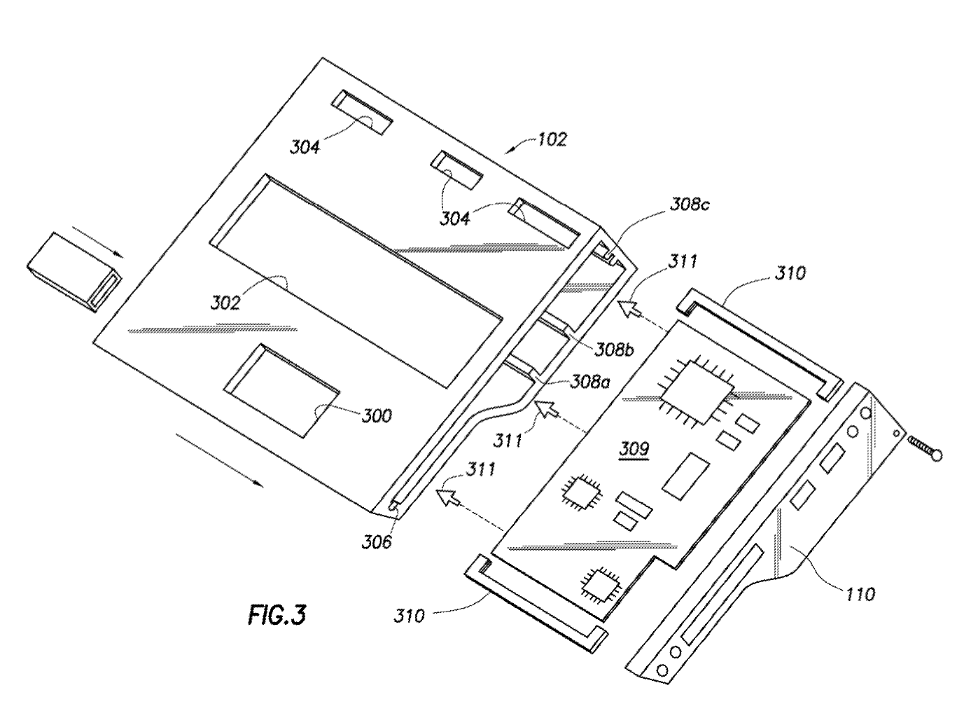

FIG. 2 shows a cross-sectional view of an illustrative die 200 used to fabricate the notebook 100 in an extrusion process. The die 200 may be manufactured using any suitable material (e.g., tool steel) and using any suitable process (e.g., metal extrusion, computer numerical control (CNC) machining, etc.). The die 200 comprises an outer component 202a and an inner component 202b. The open space/cavity 204 between the components 202a and 202b defines the shape and parameters of a notebook chassis extruded through the die 200.

There are several methods for forming internal cavities within dies. One such method includes the use of a hollow billet and a floating mandrel or a fixed mandrel (i.e., a mandrel that is integrated into a dummy block and stem). A floating mandrel floats in slots in the dummy block and aligns itself in the die during extrusion. If a solid billet is used in lieu of a hollow billet, it must first be pierced by the mandrel prior to extrusion through the die. A special press may be used to control the mandrel independently from the ram. The solid billet also could be used with a spider die, porthole die or bridge die. All of these types of dies incorporate the mandrel in the die and have legs that hold the mandrel in place. Generally, during extrusion, the metal divides and flows around the legs, leaving weld lines in the final product.

Because the space 204 defines the shape of the notebook chassis produced using the die 200 (e.g., the shape of the chassis 102), the space 204 may be altered as desired to manipulate the shape of the chassis. Stated in another way, when the components 202a and 202b are altered with protrusions or indentations, the space 204 also is altered, thereby manipulating the shape of the chassis produced using the die 200. These protrusions and indentations may be designed to manipulate the chassis shape so that, for instance, the chassis accommodates a desired type of circuit logic.

Thus, as shown in FIG. 2, the illustrative inner component 202b comprises protrusion 206 and indentations 208a, 208b and 208c. Protrusion 206 causes an indentation to be formed in the chassis 102, while indentations 208a-208c cause protrusions to be formed in the chassis 102. Extruding material through the die 200 thus produces the chassis 102 shown in FIG. 3. Referring to FIGS. 2 and 3, the protrusion 206 results in the indentation 306, while indentations 208a-208c result in protrusions 308a-308c, respectively. Although the die 200 may be designed as desired to result in various protrusions and indentations in the chassis 102, the particular indentation 306 and protrusions 308a-308c shown in FIG. 3 facilitate the insertion and coupling of a printed circuit board (PCB) 309 within the chassis 102.

Specifically, the PCB 309 couples to multiple shock mounts 310, as shown. In turn, once the shock mounts 310 are coupled to the PCB 309, the PCB 309 is slid into the chassis 102 as indicated by arrows 311. The shock mounts 310 mate with the indentation 306 and the protrusion 308c, while the PCB 309 itself mates with the protrusions 308a-308b (e.g., using indentations on the underside of the PCB 308; not specifically shown). The PCB 309, when slid inside the chassis 102 a sufficient distance, blind-mates to connectors within the chassis 102. These connectors enable circuit logic on the PCB 309 to communicate with other electrical components coupled to the chassis 102, including a display, hard drives, peripherals, etc.

The fact that the indentations, protrusions and shock mounts enable the PCB 309 to slide in and out of the chassis 102 provides for easy access to the PCB 309 (e.g., for repairs). The chassis 102 does not need to be dismantled to any significant degree in order to access the PCB 309 or other circuit components housed within the chassis 102.

The shock mounts 310 serve at least two purposes. First, as explained, they enable the PCB 309 to slide in and out of the chassis 102. Second, because they are made of certain types of material (e.g., thermoplastic elastomers), the shock mounts 310 introduce a degree of shock absorption between the PCB 309 and the chassis 102. Specifically, instead of being rigidly connected to the chassis 102, thereby increasing the likelihood of damage to the PCB 309 upon physical insult to the chassis 102, the shock mounts 310 can absorb at least some of the shock introduced to the chassis 102. Such shock absorption protects the integrity of the PCB 309. Other components may be similarly mounted within the chassis 102.

In addition to extruded protrusions and indentations, the chassis 102 may be further modified after the extrusion process to allow access to components housed within the chassis 102. These modifications may be made, for, example, using a stamping process or a CNC machine cutting process. As shown in FIG. 3, the chassis 102 has been stamped or cut to include an orifice 300 through which a touchpad will be exposed for user access. Similarly, orifice 302 will expose a keyboard for user access, while orifices 304 will expose miscellaneous features (e.g., power button, volume controls) for user access. Indentations and/or protrusions may be created within the chassis 102 for mounting of touchpads, keyboards, etc. as desired. Although the PCB 309 is shown as being slid into the chassis 102 from one end of the chassis, the PCB 309 and/or other components also may be slid into the chassis 102 from the opposite end of the chassis.

Once the contents of the chassis 102 have been slid or otherwise inserted into the chassis 102, the ends of the chassis 102 may be closed using endcaps 110. As described above, the endcaps 110 comprise orifices for jacks, USB ports, etc. which may exposed from inside the chassis 102 through the endcaps 110. The endcaps 110 may be screwed onto the chassis 102 or, alternatively, may snap-on to the chassis 102.

Additional devices, such as a display, also may couple to the chassis 102. In particular, the chassis 102 may be modified post-extrusion to include features to which a display may couple for mechanical support. Further, an orifice may be created in the chassis 102 through which electrical wires (e.g., for power, data, etc.) may pass between the display and circuitry within the chassis 102.

If desired, the chassis 102 may be anodized to a particular color. A standard anodizing process may be used. A dye having the desired color may be added to the anodizing acid bath for the color tint process.

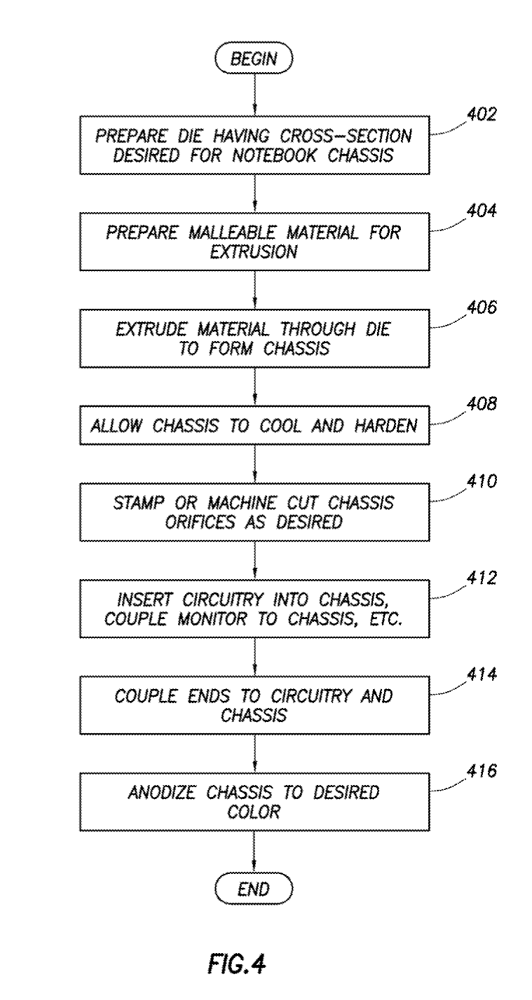

FIG. 4 shows a flow diagram of an illustrative method 400 performed in accordance with various embodiments. The method 400 begins by preparing a die having a cross-section that matches the desired cross-section of a notebook chassis (block 402). The method 400 continues by preparing malleable material (e.g., aerospace-grade aluminum) for extrusion (block 404). Such preparation includes heating the stock material to be extruded, loading the material into a container that feeds the die, placing a dummy block behind the material, and using a ram to extrude the material through the die. The extruded material may then be stretched, heat-treated or “cold-worked” (i.e., strengthening of a material by increasing the material's dislocation density) as desired.

The method 400 further comprises extruding the material through the die (block 406) and allowing the chassis to cool and harden (block 408). The chassis is “monolithically” extruded, meaning that the extruded chassis (e.g., the chassis 102, described above) comprises a shell that is monolithic and seamless. The chassis is monolithic and seamless in that virtually the entire chassis (excluding endcaps) is produced during a single extrusion process. The monolithically extruded chassis is in contrast to a different chassis that is an assembly of several independently extruded parts.

The method 400 continues by stamping or cutting one or more chassis orifices, as desired (block 410). As previously explained, the orifices may be created to route wires therethrough, to provide access to devices (e.g., keyboard, touchpad, etc.) within the chassis 102 from outside the chassis, for ventilation, jacks, ports, aesthetics, mechanical support, etc.

The method 400 still further comprises inserting circuit boards and/or other devices into the chassis, coupling a display to the chassis, etc. (block 412). As explained above, in at least some embodiments, inserting a circuit board or other device comprises sliding the board or device into the chassis using shock mounts, indentations and/or protrusions, as shown in FIG. 3. The method 400 comprises coupling end-caps to the chassis (block 414) and anodizing the chassis to a desired color (block 416). The steps of method 400 may be modified as desired, including the rearrangement, addition and/or deletion of steps.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method that comprises extruding material through a die to produce a notebook computer chassis having multiple sides that encapsulate a volume.

2. The method of claim 1 further comprising:
as part of said extrusion, creating at least one of a protrusion or an indentation in said chassis; and
sliding a device into the chassis using said at least one of the protrusion or the indentation, said device couples to the at least one of the protrusion or indentation using one or more shock mounts.

3. The method of claim 1, wherein the computer chassis houses a processor, a hard drive and a fan.

4. The method of claim 1, wherein the material comprises aerospace-grade aluminum.

5. The method of claim 1 further comprising:
creating an orifice in the chassis; and
mounting a device within the chassis, said device is accessible from outside the chassis via said orifice.

6. A monolithically-extruded portable computer chassis.

7. The computer chassis of claim 6, wherein the chassis comprises aerospace-grade aluminum.

8. The computer chassis of claim 6, wherein the chassis comprises:
at least one of an extruded indentation or an extruded protrusion; and
an electronic device that is capable of sliding in and out of said chassis while mating to the at least one of the extruded indentation or the extruded protrusion.

9. The computer chassis of claim 6, wherein the computer chassis comprises a system selected from the group consisting of a notebook computer, a desktop computer and a personal digital assistant (PDA).

10. A notebook computer, comprising:
extruded means for housing circuitry; and
extruded means for mating to said circuitry, the circuitry capable of sliding in and out of the means for housing using the means for mating.

11. The notebook computer of claim 10, wherein the extruded means for housing comprises a chassis and the extruded means for mating comprises at least one of an indentation or a protrusion on said chassis.

12. The notebook computer of claim 10, wherein the circuitry mates with the means for mating using means for absorbing shock.

13. The notebook computer of claim 10, wherein the means for housing comprises aerospace-grade aluminum.

14. The notebook computer of claim 10, wherein both the extruded means for housing and the extruded means for mating are monolithically extruded.
